(19) United States
(12) Patent Application Publication
(10) Pub. No.: US 2025/0231232 A1
(43) Pub. Date: Jul. 17, 2025

(54) TEST DEVICE, ELECTRONIC DEVICE, AND OPERATING METHOD OF TEST DEVICE

(71) Applicant: Samsung Electronics Co., Ltd., Suwon-si (KR)

(72) Inventors: Ingoo Heo, Suwon-si (KR); Hyeonggyu Kim, Suwon-si (KR)

(21) Appl. No.: 18/815,859

(22) Filed: Aug. 27, 2024

(30) Foreign Application Priority Data
Jan. 12, 2024 (KR) 10-2024-0005674

(51) Int. Cl. G01R 31/28

(52) U.S. Cl. CPC G01R 31/2806; G01R 31/2803; G01R 31/2818

(57) ABSTRACT

A test device, an electronic device, and an operating method of the test device are provided. The test device schedules an execution order of test operations on target semiconductor intellectual properties (IPs), based on metadata and instruction data, the metadata including a dependency relationship indication between a plurality of semiconductor IPs and a time-out time of the test operation on each of the semiconductor IPs, and the instruction data including an operation and an address of each target semiconductor IP and a test sample, and perform the test operations on the target semiconductor IPs in the scheduled execution order.

### CROSS-REFERENCE TO RELATED APPLICATION

This application is based on and claims priority under 35 U.S.C. § 119 to Korean Patent Application No. 10-2024-0005674, filed on Jan. 12, 2024, in the Korean Intellectual Property Office, the disclosure of which is incorporated by reference herein in its entirety.

### BACKGROUND

Aspects of the inventive concept relate to a self-test, and more particularly, to a test device, an electronic device, and an operating method of the test device.

In designing semiconductor chips, debugging is essential and technology for diagnosing a semiconductor intellectual property (IP) of a semiconductor chip is required in various standards. A self-test is a countermeasure against fault attacks and is typically required as a safety feature for automotive products. Accordingly, a self-test is built in a semiconductor chip to independently test various types of semiconductor IPs of the semiconductor chip.

However, there are cases where testing semiconductor IPs with software is not allowed, depending on a standard rating. As semiconductor chips become highly integrated, when a test function is built in each of individual semiconductor IPs, the size of each semiconductor IP increases because a test logic is added to each semiconductor IP, and it takes a lot of time and resources to test the semiconductor IPs individually. To reduce the total test time, technology for testing multiple semiconductor IPs in parallel is desired.

### SUMMARY

Aspects of the inventive concept provide a test device for detecting a defect in each of multiple semiconductor intellectual properties (IPs) built in a chip, an electronic device, and an operating method of the test device.

According to an aspect of the inventive concept, an electronic device includes a register configured to store mode data and identification data, the mode data specifying timing schemes for test operations on semiconductor intellectual properties (IPs), and the identification data specifying each of target semiconductor IPs to undergo a test operation among a plurality of semiconductor IPs; a fetcher configured to fetch metadata and a plurality of pieces of instruction data from a memory, the metadata including a dependency relationship indication between and among the plurality of semiconductor IPs and a time-out time of the respective test operation on each of the plurality of semiconductor IPs, and the plurality of pieces of instruction data each including a type of operation and an address of each of a respective target semiconductor IP and a test sample according to the type of operation; a driver configured to communicate with the target semiconductor IPs according to a scheduled test execution order; and a manager configured to schedule an execution order of test operations on the target semiconductor IPs, based on the mode data and the metadata, to provide the plurality of pieces of instruction data to the driver according to the scheduled test execution order, and to output a test result based on a test response value of each of the target semiconductor IPs from the driver.

According to another aspect of the inventive concept, an electronic device includes a plurality of semiconductor IPs, a memory storing metadata and a plurality of pieces of instruction data, the metadata including a dependency relationship indication between and among the plurality of semiconductor IPs and a time-out time of a test operation on each of the plurality of semiconductor IPs, and the plurality of pieces of instruction data each including a type of operation and an address of a respective one of the plurality of semiconductor IPs and a test sample according to the type of operation, and a tester configured to schedule an execution order of test operations on target semiconductor IPs, based on the metadata and identification data received from a processor and specifying each of the target semiconductor IPs, to perform the test operations on the target semiconductor IPs in the scheduled execution order based on instruction data regarding the target semiconductor IPs, and to provide the processor with a test result based on a test response value of each of the target semiconductor IPs.

According to a further aspect of the inventive concept, an operating method of a test device includes receiving identification data from a processor, the identification data specifying each of target semiconductor IPs to undergo a test operation among a plurality of semiconductor IPs, fetching metadata and a plurality of pieces of instruction data from a memory, the metadata including a dependency relationship indication between the plurality of semiconductor IPs and a time-out time of the test operation on each of the plurality of semiconductor IPs, and the plurality of pieces of instruction data each including a type of operation and an address of each of the target semiconductor IPs and a test sample according to the type of operation, scheduling an execution order of test operations on the target semiconductor IPs based on the identification data and the metadata, and performing the test operations on the target semiconductor IPs in the scheduled execution order based on the plurality of pieces of instruction data.

### BRIEF DESCRIPTION OF THE DRAWINGS

Embodiments will be more clearly understood from the following detailed description taken in conjunction with the accompanying drawings in which:

FIG. 1 is a block diagram of a system according to an embodiment;

FIG. 2 is a diagram illustrating a memory according to an embodiment;

FIG. 3 is a diagram showing an example of metadata in FIG. 2;

FIG. 4 is a diagram showing an example of instruction data in FIG. 2;

FIG. 5 is a block diagram of a test device according to an embodiment;

FIG. 6 is a flowchart illustrating a sequential mode according to an embodiment;

FIG. 7 is a diagram illustrating an example of scheduling an execution order in the sequential mode, according to an embodiment;

FIG. 8 is a diagram showing an example of the scheduled execution order and time-out in FIG. 7;

FIG. 9 is a flowchart illustrating a parallel mode according to an embodiment;

FIG. 10 is a diagram illustrating an example of scheduling an execution order in the parallel mode, according to an embodiment;

FIG. 11 is a diagram showing an example of the scheduled execution order and time-out in FIG. 10;

FIG. 12 is a diagram illustrating an example of scheduling an execution order in the parallel mode, according to an embodiment;

FIG. 13 is a diagram showing an example of the scheduled execution order and time-out in FIG. 12; and

FIG. 14 is a flowchart of an operating method of a test device, according to an embodiment.

### DETAILED DESCRIPTION OF THE EMBODIMENTS

Hereinafter, embodiments are described in detail with reference to the accompanying drawings.

As is traditional in the field of the disclosed technology, features and embodiments are described, and illustrated in the drawings, in terms of functional blocks, units, and/or modules. Those skilled in the art will appreciate that these blocks, units, and/or modules are physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or similar, they may be programmed using software (e.g., microcode) to perform various functions discussed herein and may optionally be driven by firmware and/or software. Alternatively, each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of the embodiments may be physically separated into two or more interacting and discrete blocks, units, and/or modules without departing from the scope of the inventive concepts. Further, the blocks, units, and/or modules of the embodiments may be physically combined into more complex blocks, units, and/or modules without departing from the scope of the inventive concepts.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

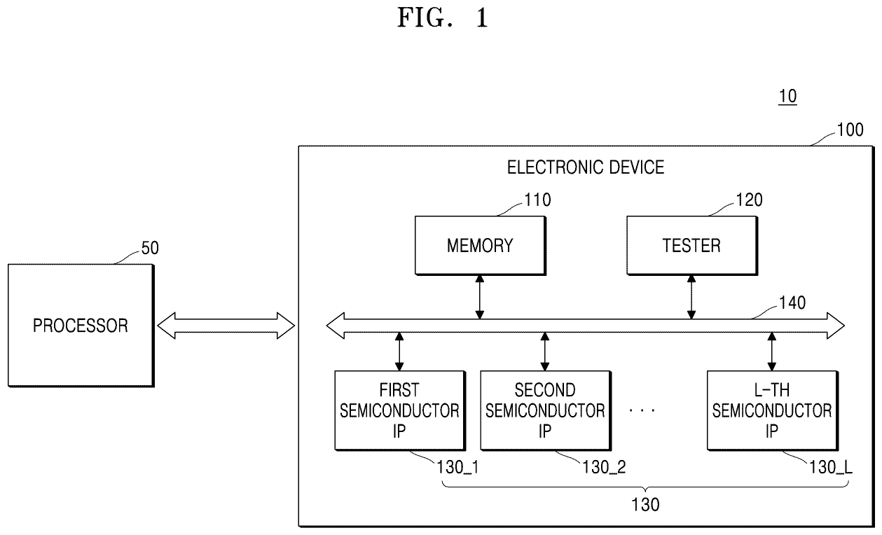

FIG. 1 is a block diagram of a system 10 according to an embodiment.

Referring to FIG. 1, the system 10 may include a processor 50 and an electronic device 100.

As a host, the processor 50 may communicate with the electronic device 100 through an interface. The processor 50 may include at least one central processing unit (CPU) core.

In an embodiment, the processor 50 may select at least one of a plurality of semiconductor intellectual properties (IPs) 130. For example, the processor 50 may select a semiconductor IP by providing the electronic device 100 with an address corresponding to the semiconductor IP.

In an embodiment, the processor 50 may instruct at least one of the plurality of semiconductor IPs 130 to perform a functional operation. The functional operation may refer to an independent function of each semiconductor IP.

In an embodiment, the processor 50 may instruct at least one of the plurality of semiconductor IPs 130 to perform a test operation. A semiconductor IP, which is instructed by the processor 50 to perform a test operation, among the plurality of semiconductor IPs 130, may be referred to as a target semiconductor IP.

The electronic device 100 may include a memory 110, a tester 120, the plurality of semiconductor IPs 130, and a bus 140. The memory 110, the tester 120, and the plurality of semiconductor IPs 130 may communicate with one another through the bus 140. In an embodiment, the electronic device 100 may include a security controller. The electronic device 100 may be implemented in a semiconductor chip such as a system-on-chip (SoC).

The memory 110 may store data. In an embodiment, the memory 110 may be or include volatile memory. For example, the volatile memory may be or include double data rate synchronous dynamic random access memory (DDR SDRAM), low power DDR (LPDDR) SDRAM, graphics DDR (GDDR) SDRAM, or Rambus DRAM (RDRAM). However, embodiments are not limited thereto. In some embodiments, the memory 110 may include non-volatile memory such as flash memory.

In an embodiment, the memory 110 may store metadata and a plurality of pieces of instruction data. The metadata may include a dependent relationship between a plurality of semiconductor IPs 130 and a time-out time of a test operation for each of the plurality of semiconductor IPs 130. The instruction data may represent an instruction for each semiconductor IP. An instruction may be referred to as a sequence.

The tester 120 may selectively, sequentially or in parallel test multiple semiconductor IPs built in a semiconductor chip and detect a defect in each semiconductor IP. The tester 120 may selectively drive multiple semiconductor IPs according to a program, check the state of each semiconductor IP, perform scheduling taking into account a test time for each semiconductor IP and a dependent relationship between semiconductor IPs, periodically test and diagnose a semiconductor IP, and manage a semiconductor IP during a test according to a semiconductor IP use request.

The tester 120 may test at least one target semiconductor IP among the plurality of semiconductor IPs 130 and provide a result of the test to the processor 50. The tester 120 may be referred to as a self-tester.

In an embodiment, the tester 120 may schedule the execution order of test operations to be performed on a plurality of target semiconductor IPs, according to a preset mode. The tester 120 may also perform the test operations in the scheduled execution order.

Each of the plurality of semiconductor IPs 130 may refer to a circuit, a chip layout design, software code, or the like that are reusable and have an independent function. When an SoC or a field programmable gate array (FPGA) circuit is designed, a microprocessor, a memory, a digital signal processor, an analog signal processor, various input/output (I/O) circuits, and the like may be used as functional blocks. For example, a semiconductor IP may include a soft IP in synthesizable register transfer level (RTL) code, a hard IP as design data that has been placed and wired according to a set process, a firm IP as a gate-level netlist having some floor planning information, a device driver for driving a circuit, a standard cell, a macroblock, a library (Stan software or firmware), or the like. Most the plurality of semiconductor IPs may be driven for register-based read or write and may have a deterministic characteristic producing the same output from a given input. The number of clock cycles taken to perform the operation may be constant. The plurality of semiconductor IPs 130 may include first to L-th semiconductor IPs 130_1 to 130_L. Here, L is an integer of at least 2. The plurality of semiconductor IPs 130 may include semiconductor IPs depending on each other, semiconductor IPs sharing resources, or semiconductor IPs not sharing resources. Each semiconductor IP may have a unique function and structure and semiconductor IPs may have different test times.

According to the embodiments described above, the quality and reliability of a device may be increased by detecting a defect in a semiconductor IP built in a chip.

In addition, a test operation may be quickly and efficiently performed on each semiconductor IP by determining in real time whether the semiconductor IP is available or whether to diagnose or stop diagnosing the semiconductor IP, taking into account the dependency between and among semiconductor IPs.

Furthermore, because the electronic device 100 is delegated a semiconductor IP test function, the electronic device 100 may reduce a burden, such as the code size of an external manager such as a CPU or resource utilization, which is caused by self-diagnosis.

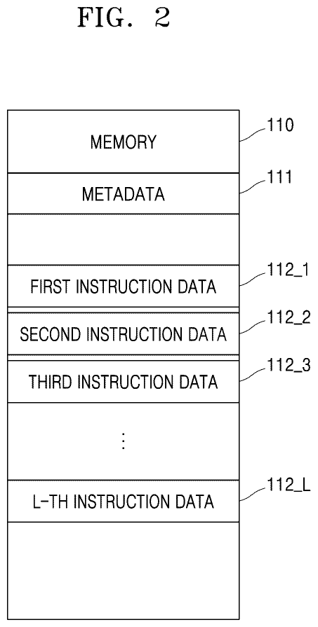

FIG. 2 is a diagram illustrating a memory 110 according to an embodiment.

Referring to FIG. 2, the memory 110 may correspond to the memory 110 in FIG. 1. The memory 110 may store metadata 111 and first to L-th instruction data 112_1 to 112_L as a program. The program stored in the memory 110 may be programmable according to a storage method.

The metadata 111 may include a value representing independency or dependency of each of the first to L-th semiconductor IPs 130_1 to 130_L and a value representing a time-out time in a test operation of each of the first to L-th semiconductor IPs 130_1 to 130_L.

The first to L-th instruction data 112_1 to 112_L may include instructions for the first to L-th semiconductor IPs 130_1 to 130_L. The number of pieces of instruction data may correspond to the number of semiconductor IPs included in the electronic device 100. The instruction data may include the type of operation of each semiconductor IP, an address corresponding to each semiconductor IP, and a test sample according to the type of operation. For example, the instruction data may include the type of operation used for a test operation, the address of a semiconductor IP, the value of a test sample used in the test operation, and a nibble strobe. The nibble strobe may include a value related to a nibble mode in which 4-bit data is transmitted at a time between a computer and a peripheral device. The nibble strobe may be a field used to mask only some data during a read or a write. The instruction data may be referred to as a sequence table. A fixed sequence table may be loaded on the memory 110, and thus, a process of loading a program to a particular memory area is avoided when an initial test is executed. Thereafter, a periodic test on demand may be executed with the loaded program.

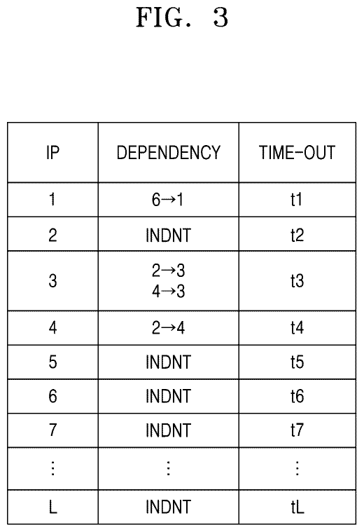

FIG. 3 is a diagram showing an example of the metadata 111 in FIG. 2.

Referring to FIGS. 2 and 3, the metadata 111 may include a dependency relationship indication DEPENDENCY and a time-out time TIME-OUT of each of the first to L-th semiconductor IPs 130_1 to 130_L.

Regarding the dependency relationship indication DEPENDENCY of the metadata 111, the dependency relationship indication DEPENDENCY of an independent semiconductor IP may have a first relationship value INDNT representing independency. For example, the dependency relationship indication DEPENDENCY of each of the second, fifth, sixth, seventh, and L-th semiconductor IPs 130_2, 130_5, 130_6, 130_7, and 130_L may have the first relationship value INDNT. Although it is illustrated in FIG. 3 that the first relationship value INDNT indicating an independent semiconductor IP is included in the dependency relationship indication DEPENDENCY of the metadata 111, embodiments are not limited thereto. In some embodiments, an independent semiconductor IP may not have a specific value instead of having the first relationship value INDNT. The dependency relationship indication DEPENDENCY of a dependent semiconductor IP may have a second relationship value representing a dependent relationship. For example, the dependency relationship indication DEPENDENCY of the first semiconductor IP 130_1 may have a second relationship value, 6→1, indicating a relationship dependent on the sixth semiconductor IP 130_6. The dependency relationship indication DEPENDENCY of the third semiconductor IP 130_3 may have a second relationship value, 2→3 and 4→2, indicating a relationship dependent on the second semiconductor IP 130_2 and the fourth semiconductor IP 130_4. The dependency relationship indication DEPENDENCY of the fourth semiconductor IP 130_4 may have a second relationship value, 2→4, indicating a relationship dependent on the second semiconductor IP 130_2. However, embodiments are not limited thereto. When one semiconductor IP is dependent on at least one semiconductor IP, the dependent semiconductor IP may be tested after the at least one semiconductor IP is completely tested. As described herein when a first semiconductor IP is dependent on a second semiconductor IP, the first semiconductor IP may be referred to as a dependent IP, and the second semiconductor IP may be referred to as a parent IP.

The time-out time TIME-OUT of the metadata 111 may include first to L-th time-out values t1 to tL respectively for the first to L-th semiconductor IPs 130_1 to 130_L. In an embodiment, each of the first to L-th time-out values t1 to tL may correspond to the number of clock cycles. However, embodiments are not limited thereto.

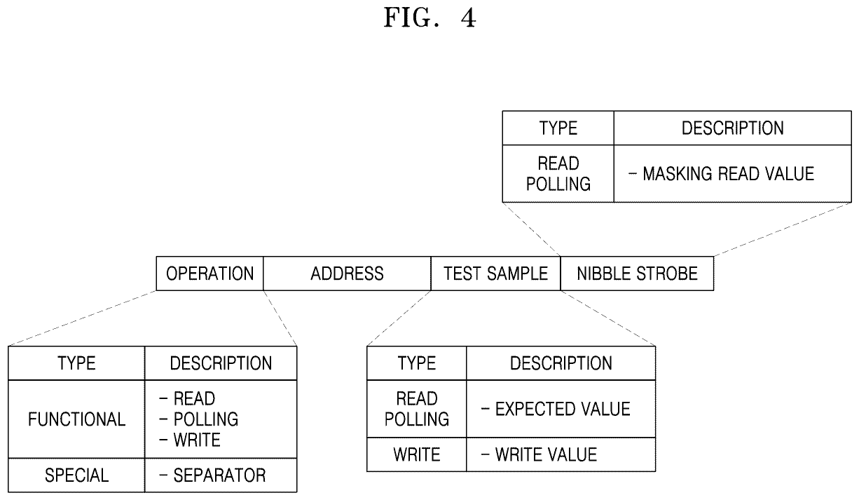

FIG. 4 is a diagram showing an example of instruction data in FIG. 2.

Referring to FIGS. 2 and 4, the instruction data of FIG. 4 may correspond to one of the first to L-th instruction data 112_1 to 112_L in FIG. 2. The instruction data of FIG. 4 may include an operation type OPERATION, an address, a test sample according to an operation type, and a nibble strobe, with respect to a target semiconductor IP. In an embodiment, the operation type OPERATION may be constituted of three bits. The address and the test sample may each be constituted of 32 bits. The nibble strobe may be constituted of eight bits.

In the operation type OPERATION, a function FUNCTIONAL may include a read operation READ, a polling operation POLLING, or a write operation WRITE. The read operation READ and the polling operation POLLING may refer to an operation of reading data stored to the address. However, the read operation READ may refer to an operation of reading data in a certain time and the polling operation POLLING may refer to an operation of reading data without a certain time limit or until the same value as an expected value is read. A polling operation POLLING may be a series of consecutive repeated read operations READ, that continue without a time limit and that continue until the same value as an expected value is read, in one embodiment. The write operation WRITE may refer to an operation of writing data to the address. A special function SPECIAL may include a separator. The separator may indicate the end number (e.g., end bit position or end bit sequence) of other instruction data. For example, the separator of the second instruction data 112_2 may indicate the end number of the first instruction data 112_1. The separator of the third instruction data 112_3 may indicate the end number of the second instruction data 112_2. However, embodiments are not limited thereto.

In the case of the read operation READ or the polling operation POLLING, the test sample may include an expected value. The expected value may refer to a value expected to be output from a target semiconductor IP when the read operation READ or the polling operation POLLING is performed. In the case of the write operation WRITE, the test sample may include a write value.

The nibble strobe may include information necessary and/or used to check a significant value every four bits. In the case of the read operation READ or the polling operation POLLING, the nibble strobe may include a masking read value.

According to the embodiment described above, when the operation type OPERATION is simplified, there is an area advantage due to a low structural complexity.

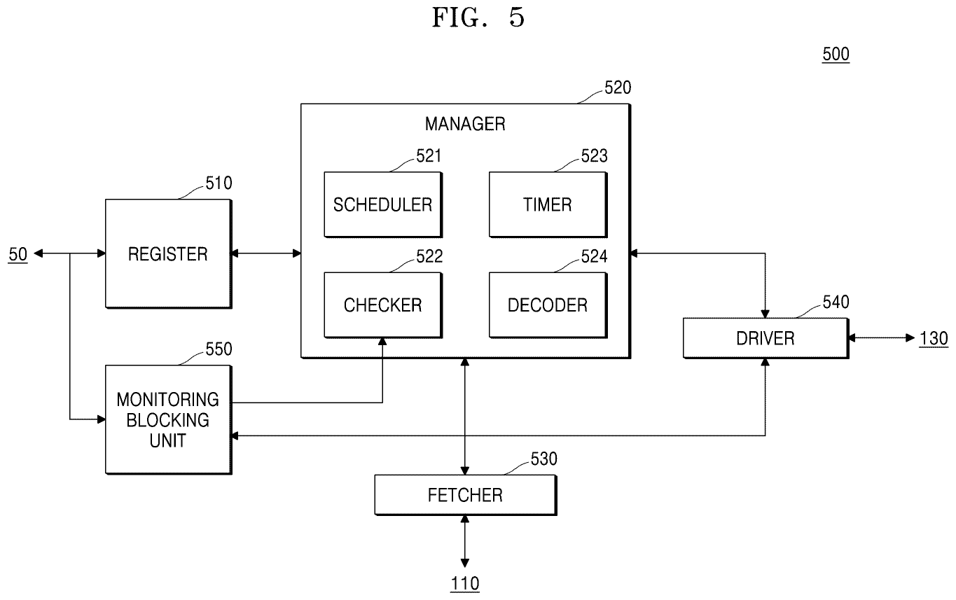

FIG. 5 is a block diagram of a test device 500 according to an embodiment.

Referring to FIG. 5, the test device 500 may correspond to the tester 120 in FIG. 1. The test device 500 may include a register 510, a manager 520, a fetcher 530, a driver 540, and a monitoring blocking unit 550. Each of the register 510, manager 520, fetcher 530, driver 540, and monitoring blocking unit 550 may be implemented with hardware and optionally with additional software, configured to perform the various steps described herein. The test device 500 may receive a clock (e.g., a clock signal) from the outside.

The register 510 may store mode data and identification data. The mode data and the identification data may be written to the register 510 by the processor 50. The mode data may include a mode value that specifies a timing scheme for a test operation on a semiconductor IP. In an embodiment, the mode data may include a first mode value indicating a sequential mode and a second mode value indicating a parallel mode. In the sequential mode, test operations may be sequentially completed. For example, after one test operation is completed, another test operation may be performed in the sequential mode. In the parallel mode, even when at least one test operation is not completed, at least one other test operation may be performed. The identification data may include an identification value specifying a target semiconductor IP to be tested among the plurality of semiconductor IPs 130. For example, when the first and second semiconductor IPs 130_1 and 130_2 are target semiconductor IPs, the identification data may include first and second identification values respectively specifying the first and second semiconductor IPs 130_1 and 130_2. The register 510 may store request data indicating a test request. The request data may be provided by the processor 50. The number of registers 510 may be at least one. Each of a plurality of registers may individually store mode data, identification data, and the like for each function.

The manager 520 may check the mode and target semiconductor IPs for scheduling the order of test operations, based on the mode data and the identification data stored in the register 510. The manager 520 may control the fetcher 530 to fetch data according to a request corresponding to request data stored in the register 510. The manager 520 may decode instruction data fetched by the fetcher 530 and transmit a decoded instruction to the driver 540. The manager 520 may schedule the execution order of test operations, based on the mode data and metadata fetched by the fetcher 530, and may provide the decoded instruction to the driver 540 according to the scheduled execution order.

In an embodiment, the manager 520 may include a scheduler 521, a checker 522, a timer 523, and a decoder 524.

The scheduler 521 may check the state of a semiconductor IP. When the semiconductor IP is in a state, e.g., a busy state, in which the semiconductor IP may not execute a subsequent instruction, the scheduler 521 may create a schedule to select another semiconductor IP. Considering that it is not possible to simultaneously test semiconductor IPs when there is dependency between the semiconductor IPs due to resource sharing or the like and that a test time is different for each semiconductor IP, the scheduler 521 may arrange the test start order of semiconductor IPs to test as many semiconductor IPs as possible in parallel.

In an embodiment, the scheduler 521 may be configured to schedule (or reorder) the execution order of test operations on target semiconductor IPs, based on identification data, mode data, and metadata. The scheduler 521 may be configured to control the fetcher 530 and the driver 540 to perform a test operation using instruction data according to the scheduled execution order. The scheduler 521 may be configured to generate a result of the test operation by using a test response value of a target semiconductor IP, which is provided from the driver 540. For example, the scheduler 521 may check whether the response value matches an expected value of the instruction data and may generate the result of the test operation. The scheduler 521 may be configured to output a result value representing the result of the test operation to the register 510.

The checker 522 may be configured to check the access of the processor 50 to a semiconductor IP that is being tested or to a semiconductor IP dependent on the semiconductor IP that is being tested. The checker 522 may store metadata fetched from the fetcher 530. The checker 522 may detect access to a semiconductor IP that is being tested or access to a semiconductor IP dependent on the semiconductor IP that is being tested.

The timer 523 may sense an abnormality, in which a test operation is not completed in a set time, or may set a notification for a periodic test operation. The timer 523 may be configured to set various times and output a notification signal (or an interrupt signal) whenever a set time is reached. In an embodiment, the timer 523 may individually set a time-out time of each test operation or comprehensively set a time-out time according to a mode. For example, in the sequential mode, the timer 523 may individually set a time-out time for each target semiconductor IP based on metadata, count the time-out time when a test operation is performed on the target semiconductor IP, and output a notification signal to the scheduler 521 when the time-out time is reached. For example, in the parallel mode, the timer 523 may receive a reordered test target list from the scheduler 521, calculate a time taken for test operations to be performed in parallel, and set a time-out time using the calculated time. In detail, in the parallel mode, the timer 523 may sum the time-out times of target semiconductor IPs based on metadata, set the sum to a time-out time, and count a time-out time when test operations are performed on the target semiconductor IPs. In an embodiment, when all test operations on target semiconductor IPs are completed, the timer 523 may subsequently output a trigger signal to the scheduler 521 at preset intervals. In this case, the scheduler 521 may control the fetcher 530 and the driver 540 to newly perform a test operation on each of the target semiconductor IPs that have undergone a test operation. For example, when all test operations on the target semiconductor IPs are completed, the scheduler 521 may subsequently schedule the execution order of test operations on the target semiconductor IPs such that test operations may be performed on the target semiconductor IPs at preset intervals. Accordingly, test operations may be performed on target semiconductor IPs at intervals set in the timer 523.

The decoder 524 may be configured to decode instruction data fetched from the fetcher 530. The decoder 524 may be configured to transmit a decoded instruction to the driver 540. In an embodiment, the decoder 524 may change the state of a finite state machine (FSM) according to the fetched instruction.

The fetcher 530 may be configured to fetch the metadata 111 from the memory 110. The fetcher 530 may be configured to fetch instruction data, which includes a type of operation and an address of each target semiconductor IP, and a test sample according to the type of operation.

The driver 540 may be configured to communicate with a target semiconductor IP according to the scheduled execution order. The driver 540 may change the decoded instruction, which is received from the manager 520, according to a bus protocol and may drive the changed instruction. The driver 540 may transmit a test response value from a target semiconductor IP to the manager 520.

The monitoring blocking unit 550 may be configured to receive, from the processor 50, an address value of a target semiconductor IP that is being tested among target semiconductor IPs and stop a test operation on the target semiconductor IP. The monitoring blocking unit 550 may be configured to stop a test operation on a semiconductor IP, reset the semiconductor IP, and allow reuse of the semiconductor IP. When the processor 50 wants to use a semiconductor IP, of which the test is stopped and the reset is impossible, the monitoring blocking unit 550 may block the semiconductor IP or notify a user that the semiconductor IP is not available. The monitoring blocking unit 550 may be referred to as a blocker.

In an embodiment, the monitoring blocking unit 550 may detect bus traffic toward a semiconductor IP that is being tested by receiving an address value corresponding to the semiconductor IP. When the processor 50 wants to use a semiconductor IP that is being tested, a test result or a test time may be incorrect, and accordingly, bus traffic may be detected to prevent errors of the test result or the like. In an embodiment, when bus traffic toward a semiconductor IP that is being used is detected, the monitoring blocking unit 550 may stop a test operation on the semiconductor IP and inform a user of an incorrect situation. For example, the monitoring blocking unit 550 may set a ready signal to be provided to the processor 50 to a logic value indicating a busy state. Alternatively, instead of changing the logic value of a ready signal, the monitoring blocking unit 550 may discard a use request (e.g., the address of a target semiconductor IP) of the processor 50. Accordingly, when bus traffic is monitored and an action such as stopping testing is taken, it may not be necessary to separately check the state of a target semiconductor IP.

In an embodiment, the monitoring blocking unit 550 may transmit the detected bus traffic to the checker 522 and the checker 522 may output an event signal indicating a fail to the register 510.

In an embodiment, the monitoring blocking unit 550 may pass the detected bus traffic to the driver 540 and the driver 540 may stop a test operation that is currently being performed on a semiconductor IP.

According to the embodiment described above, the test device 500 may include a timer to perform periodic diagnosis and may support the diagnosis and handling of a time-out situation in which the diagnosis is not completed until an expected execution time elapses.

According to the embodiment described above, the test device 500 may support diagnosis start scheduling based on execution time information and dependency information of a target semiconductor IP subject to diagnosis.

According to the embodiment described above, the test device 500 may provide user convenience by processing a user request during a periodic test.

According to the embodiment described above, a simple programming flow may be provided by setting and checking the test device 500 or a device including the test device 500 during on-demand diagnosis.

According to the embodiment described above, latent fault detection may be possible simply by adding and selecting a test target to the test device 500 without changing the structure of the test device 500.

According to the embodiment described above, the test device 500 may have a relatively simple structure compared to a general processor or a device having a similar structure to the general processor and may thus be used in area-sensitive products.

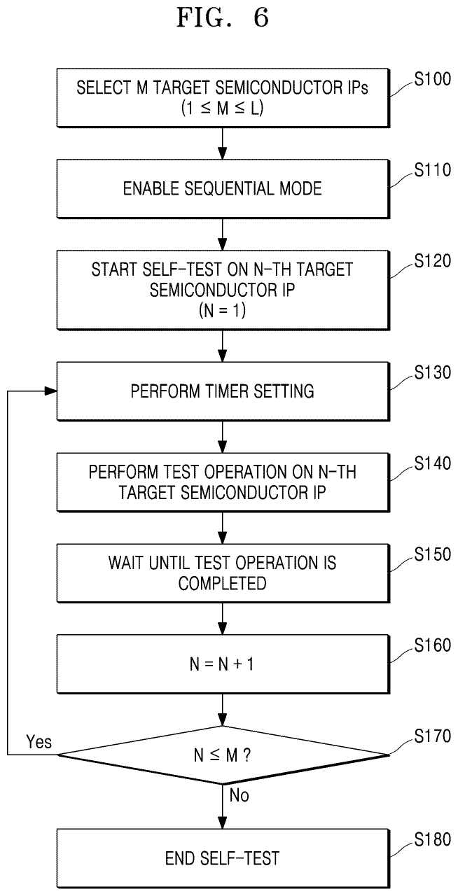

FIG. 6 is a flowchart illustrating a sequential mode according to an embodiment.

Referring to FIG. 6, M target semiconductor IPs may be selected in operation S100. For example, the M target semiconductor IPs may be selected automatically by a controller, or may be selected based on a user-input selection. Here, M is a natural number from 1 to L. The sequential mode may be enabled in operation S110. A self-test on one target semiconductor IP may start in operation S120. At this time, N is a number that specifies a target semiconductor IP and assumed to be an integer from 1 to M. Timer setting may be performed in operation S130. In this case, a time-out time of the target semiconductor IP that is currently being self-tested may be set. In the sequential mode, after a test on one semiconductor IP is completed, a test on a subsequent semiconductor IP may be performed and a time-out time may be set before each test starts. For example, the timer 523 may set a time-out value of the target semiconductor IP as a time-out time based on the time-out time TIME-OUT of the metadata 111. A test operation may be performed on the target semiconductor IP in operation S140. Waiting may occur until the test operation on the target semiconductor IP is completed in operation S150. A subsequent target semiconductor IP may be selected in operation S160. Operations S130 to S170 may be repeatedly performed such that the last target semiconductor IP in an execution order is lastly tested, that is, until N>M in operation S170. After operation S170, the self-test may be ended in operation S180.

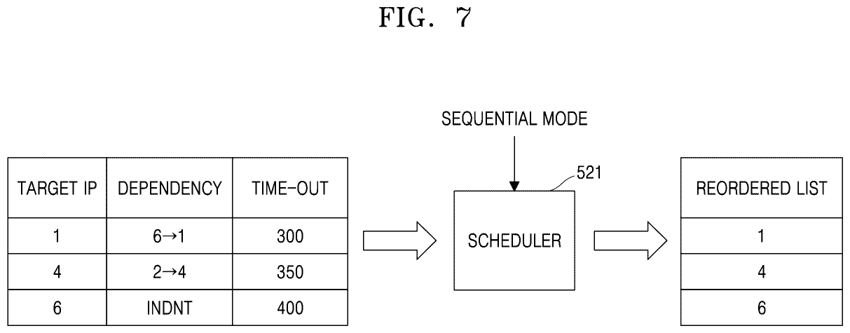

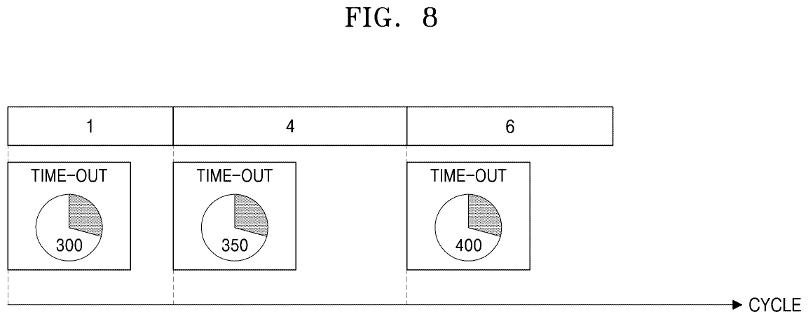

FIG. 7 is a diagram illustrating an example of scheduling an execution order in the sequential mode, according to an embodiment. FIG. 8 is a diagram showing an example of the scheduled execution order and time-out in FIG. 7.

Referring to FIGS. 7 and 8, in an embodiment, mode data may include a first mode value indicating a sequential mode. The manager 520 may sequentially schedule a test execution on target semiconductor IPs such that, after a test operation on one target semiconductor IP is completed, a test operation on another target semiconductor IP is performed.

Referring to FIGS. 3 and 7, it is assumed that target semiconductor IPs TARGET IP are the first, fourth, and sixth semiconductor IPs. In this case, the dependency relationship indication DEPENDENCY of each of the first, fourth, and sixth semiconductor IPs may be as shown in FIGS. 3 and 7. In the time-out time TIME-OUT, the time-out values of the first, fourth, and sixth semiconductor IPs are assumed to be respectively 300, 350, and 400. At this time, each of the time-out values 300, 350, and 400 may be the number of clock cycles. One cycle may correspond to one period of a clock. Because the current mode is set to the sequential mode, the scheduler 521 may schedule execution of test operations in the order of the first, fourth, and sixth semiconductor IPs, regardless of the dependency relationship indication DEPENDENCY and the time-out time TIME-OUT.

Referring to FIGS. 3, 7, and 8, a test operation on the first semiconductor IP may be performed first. At this time, the timer 523 may count clock cycles from the start of the test operation performed on the first semiconductor IP. When the test operation on the first semiconductor IP is completed within 300 cycles, a test operation may be performed on the fourth semiconductor IP. Otherwise, when the test operation on the first semiconductor IP is not completed until the number of counted cycles reaches 300, a test result for the first semiconductor IP may be processed as a fail and a test operation may be performed on the fourth semiconductor IP. The timer 523 may newly count clock cycles from the start of the test operation on the fourth semiconductor IP. When the test operation on the fourth semiconductor IP is completed within 350 cycles, a test operation may be performed on the sixth semiconductor IP. Otherwise, when the test operation on the fourth semiconductor IP is not completed until the number of counted cycles reaches 350, a test result for the fourth semiconductor IP may be processed as a fail and a test operation may be performed on the sixth semiconductor IP. The timer 523 may newly count clock cycles from the start of the test operation on the sixth semiconductor IP.

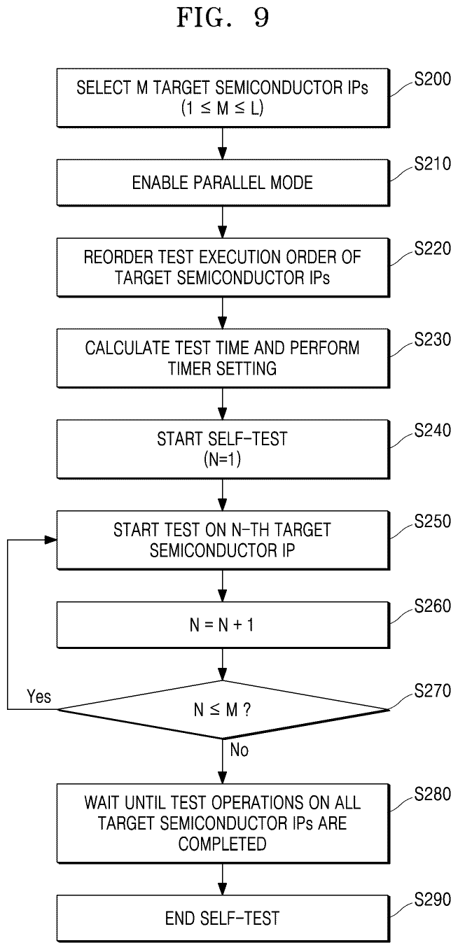

FIG. 9 is a flowchart illustrating a parallel mode according to an embodiment.

Referring to FIG. 9, operation S200 may be the same as operation S100. A parallel mode may be enabled in operation S210. The execution order of target semiconductor IPs may be reordered in operation S220. A test time may be calculated and timer setting may be performed in operation S230. The test time may correspond to the sum of time-out times, as described above. The sum of the time-out times of the target semiconductor IPs may be set by the timer 523 as the test time. A self-test may be started in operation S240. A test on an N-th target semiconductor IP among the reordered target semiconductor IPs may be started in operation S250. A subsequent target semiconductor IP may be selected in operation S260. Operations S250 to S270 may be repeatedly performed such that the last target semiconductor IP in the reordered list is lastly tested, that is, until N>M in operation S270. In the parallel mode, the execution order of target semiconductor IPs may be determined based on a test execution time and dependency of each of the target semiconductor IPs. A time-out time may be once set to a calculated parallel test time. Before a test on a target semiconductor IP is completed, a test on another target semiconductor IP that has no dependency (i.e., that is independent) may be started. The test device 500, which lists test targets, may find an optimal execution time, calculate a test time based on the list of the test targets, and set a time-out time. Waiting may occur until the test operation on all of the target semiconductor IPs is completed in operation S280 after operation S270. The self-test may be ended in operation S290.

According to the embodiment described above, the total test time may be reduced by simultaneously performing test operations on as many semiconductor IPs as possible in the parallel mode.

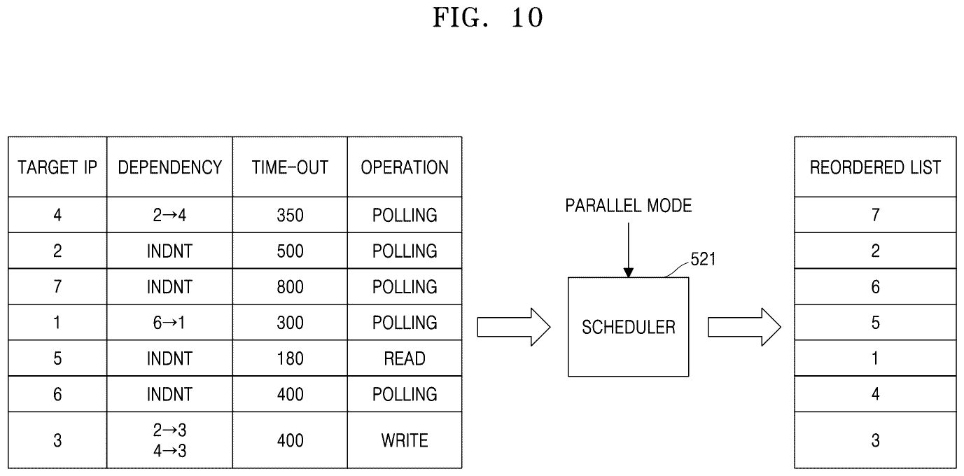

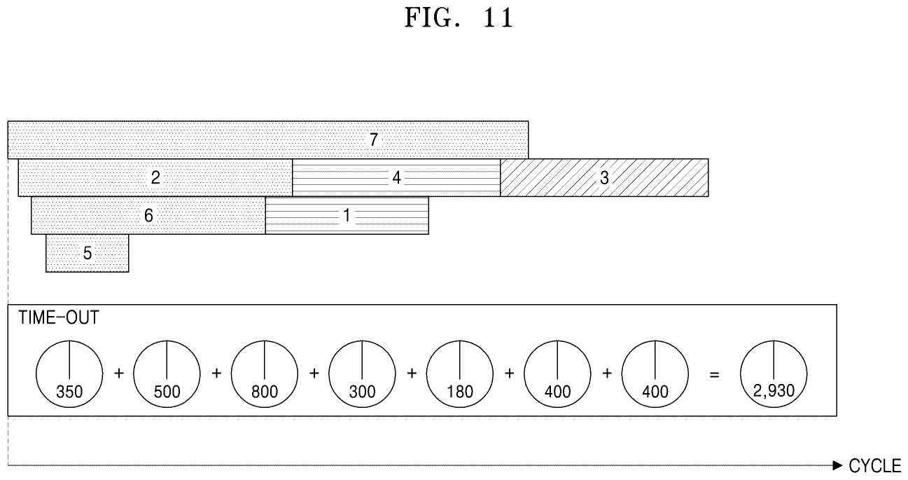

FIG. 10 is a diagram illustrating an example of scheduling an execution order in the parallel mode, according to an embodiment. FIG. 11 is a diagram showing an example of the scheduled execution order and time-out in FIG. 10.

Referring to FIGS. 10 and 11, in an embodiment, mode data may include a second mode value indicating the parallel mode. Metadata may include first relationship values representing independency between a first target semiconductor IP and a second target semiconductor IP, a first time-out value representing the time-out time of the first target semiconductor IP, and a second time-out value representing the time-out time of the second target semiconductor IP. Metadata for a plurality of pairs of target semiconductor IPs may be used, to represent interdependency and time-out values for each pair. For example, data about each pair of target semiconductor IPs having a dependency relationship in relation to each other may be included in the metadata. Using just two target semiconductor IPs as an example, a plurality of pieces of instruction data may include first instruction data and second instruction data. The first instruction data may include a first value indicating a polling operation and a first expected value that is expected from a first polling operation performed on the first target semiconductor IP. The second instruction data may include the first value and a second expected value that is expected from a second polling operation performed on the second target semiconductor IP. The manager 520 may schedule the first target semiconductor IP and the second target semiconductor IP for test execution, based on the first time-out value and the second time-out value, such that a time during which a test operation is performed on the first target semiconductor IP partially overlaps a time during which a test operation is performed on the second target semiconductor IP, so that the test operations on the first and second target semiconductor IPs are performed in parallel. In this case, the first polling operation and the second polling operation may be simultaneously performed, for example, using alternating polling signals, so that when one of the first polling operation and the second polling operation results in a fail, the other polling operation continues to be performed. In one embodiment, the scheduler 521 may schedule the execution order such that execution of a target semiconductor IP corresponding to a larger time-out value between the first time-out value and the second time-out value is initiated before a target semiconductor IP corresponding to a smaller time-out value between the first time-out value and the second time-out value.

Referring to FIGS. 3 and 10, it is assumed that target semiconductor IPs TARGET IP are the first to seventh semiconductor IPs and that the order in which the first to seventh semiconductor IPs are initially selected is random as shown in FIG. 10. The dependency relationship indication DEPENDENCY of each of the first to seventh semiconductor IPs may be as shown in FIGS. 3 and 7. In the time-out time TIME-OUT, the time-out values of the first to seventh semiconductor IPs are assumed to be respectively 300, 500, 400, 350, 180, 400, and 800. Each time-out value may be the number of clock cycles. It is assumed that the types of operations performed in a test operation on each of the first to seventh semiconductor IPs are as shown in FIG. 10. Because the current mode is set to the parallel mode, the scheduler 521 may schedule the execution order of test operations on the first to seventh semiconductor IPs, based on the dependency relationship indication DEPENDENCY and the time-out time TIME-OUT. Independent target semiconductor IPs may be tested in parallel in the parallel mode. The priority of operations performed in parallel may vary with time-out values. For example, referring to FIG. 10, because the second, fifth, sixth, and seventh semiconductor IPs are independent, test operations on the second, fifth, sixth, and seventh semiconductor IPs may be performed in parallel. When the second, fifth, sixth, and seventh semiconductor IPs are prioritized in descending order of time-out values, the second, fifth, sixth, and seventh semiconductor IPs may be sorted as in a reordered list in FIG. 10. The dependency relationship indication DEPENDENCY of each of the first, third, and fourth semiconductor IPs may be as shown in FIG. 10. Accordingly, following the second, fifth, sixth, and seventh semiconductor IPs, the first, third, and fourth semiconductor IPs may be sorted as in the reordered list in FIG. 10.

Referring to FIGS. 10 and 11, a test operation on the seventh semiconductor IP, a test operation on the second semiconductor IP, a test operation on the sixth semiconductor IP, and a test operation on the fifth semiconductor IP may be performed in parallel, with each being initiated sequentially, and then all four being performed simultaneously. Control operation for the test operations on the seventh semiconductor IP, the second semiconductor IP, the sixth semiconductor IP, and the fifth semiconductor IP may be sequentially performed (e.g., test operations maybe initiated) in the order of seventh semiconductor IP, the second semiconductor IP, the sixth semiconductor IP, and the fifth semiconductor IP. Whether an operation (e.g., a polling, write, or read operation) of a semiconductor IP has been completed may be checked through a polling of the register 510. When the operation of one of these semiconductor IPs has not been completed, a subsequently initiated semiconductor IP may be given a test opportunity, and the states of semiconductor IPs may be repeatedly checked in turn in this manner until the operation of each of the semiconductor IPs is completed. For example, a test operation may be performed on the seventh semiconductor IP. For example, a polling operation POLLING may be performed on the seventh semiconductor IP. When a test response value of the seventh semiconductor IP is different from an expected value, the test operation on the seventh semiconductor IP may be stopped and a test operation may be performed on the second semiconductor IP. At this time, a polling operation POLLING may be performed on the second semiconductor IP. When a test response value of the second semiconductor IP is different from an expected value, the test operation on the second semiconductor IP may be stopped and a test operation may be performed on the sixth semiconductor IP. At this time, a polling operation POLLING may be performed on the sixth semiconductor IP. When a test response value of the sixth semiconductor IP is different from an expected value, the test operation on the sixth semiconductor IP may be stopped and a test operation may be performed on the fifth semiconductor IP. At this time, a read operation READ may be performed on the fifth semiconductor IP. When a test response value of the fifth semiconductor IP is different from an expected value, a test result for the fifth semiconductor IP may be determined to be a fail and the test operation on the fifth semiconductor IP may be ended. Otherwise, when the test response value of the fifth semiconductor IP is the same as the expected value, the test result for the fifth semiconductor IP may be determined to be a pass and the test operation on the fifth semiconductor IP may be completed.

In some embodiments, when the test operation on one of the semiconductor IPs is the polling operation POLLING, test operations on other semiconductor IPs may be performed in parallel. For example, when the test operation of the fifth semiconductor IP is the polling operation POLLING, the test operations on the second, fifth, sixth, and seventh semiconductor IPs may be performed in parallel.

In some embodiments, a time-out value of one semiconductor IP may be smaller than a time-out value of another semiconductor IP. For example, a time-out value for the sixth semiconductor IP may be smaller than a time-out value for the second semiconductor IP. In this case, the test operation on the sixth semiconductor IP may be completed before the test operation on the second semiconductor IP. In this case, the test operation on the first semiconductor IP may be performed. For example, the test operation on the first semiconductor IP may be performed in parallel with the test operation on the second semiconductor IP, which is still ongoing. At this time, in one embodiment, the polling operation POLLING may be performed on the first semiconductor IP. When a test response value of the first semiconductor IP is different from an expected value, the test operation on the first semiconductor IP may be stopped and at the same time, a test operation may be performed on the fourth semiconductor IP. Therefore, the test operations on the first and fourth semiconductor IPs may be performed in parallel. When the test operation on the fourth semiconductor IP is completed, a test operation may be performed on the third semiconductor IP. As described above, multiple semiconductor IPs with no mutual influence may be tested simultaneously and a test execution time may be relatively short compared to the sequential mode.

In an embodiment, the timer 523 may sum the first time-out value and the second time-out value and set a sum time-out value. Based on the sum time-out value, whether the test operations on the first target semiconductor IP and the second target semiconductor IP are timed out may be determined. The same principle may be used when more than two target semiconductor IPs are being tested. The scheduler 521 may process a test result for the timed-out target semiconductor IP as a fail. For example, in the example of FIGS. 10 and 11, the sum time-out time TIME-OUT may be 2,930 that is the sum of 350, 500, 800, 300, 180, 400, and 400. The timer 523 may count the number of cycles from the start of the test operation on the seventh semiconductor IP. When the counted number of cycles reaches 2,930, this means that a time-out has occurred on all of the test operations. In the embodiment of FIG. 11, if all of the test operations do not time-out, then an overall time taken for test operations on all seven semiconductor IPs can be shortened.

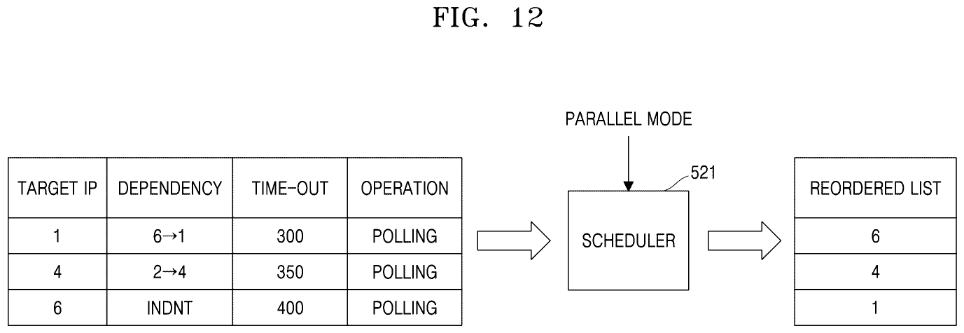

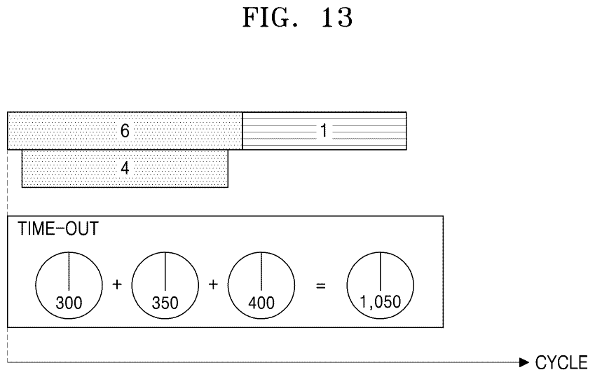

FIG. 12 is a diagram illustrating an example of scheduling an execution order in the parallel mode, according to an embodiment. FIG. 13 is a diagram showing an example of the scheduled execution order and time-out in FIG. 12.

Referring to FIGS. 12 and 13, in an embodiment, mode data may include a second mode value indicating the parallel mode. Metadata may include first relationship values representing independency between pairs of target semiconductor IPs. For each pair of target semiconductor IPs, a plurality of pieces of instruction data may include first instruction data and second instruction data. As described above with reference to FIGS. 10 and 11, the first instruction data may include the first value indicating a polling operation and the first expected value that is expected from the first polling operation performed on the first target semiconductor IP. The second instruction data may include a second value, which indicates an operation different from the polling operation, and a value according to the operation, which is different from the polling operation and performed on the second target semiconductor IP. The operation different from the polling operation may include the read operation READ or the write operation WRITE. The value according to the operation different from the polling operation may include an expected value or a write value. The scheduler 521 may schedule a test on the first target semiconductor IP to be executed before a test on the second target semiconductor IP such that a time during which a test operation is performed on the first target semiconductor IP partially overlaps a time during which a test operation is performed on the second target semiconductor IP so that the test operations on the first and second target semiconductor IPs are performed in parallel and another operation is performed when the first polling operation fails.

Referring to FIGS. 3 and 12, it is assumed that target semiconductor IPs TARGET IP are the first, fourth, and sixth semiconductor IPs, as shown in FIG. 7. Thus, there are three target semiconductor IPs in this case. It is assumed that the type of operation of each of the first, fourth, and sixth semiconductor IPs is a polling operation POLLING. However, embodiments are not limited thereto. Because an independent relationship is formed between the fourth and sixth semiconductor IPs, test operations on the fourth and sixth semiconductor IPs may be performed in parallel. When the fourth and sixth semiconductor IPs are prioritized in descending order of time-out values, the sixth semiconductor IP may be listed above, and may initiate a test operation prior to the fourth semiconductor IP.

In an embodiment, the metadata may further include a second relationship value indicating a relationship in which a third target semiconductor IP is dependent on the fourth target semiconductor IP. The pieces of instruction data may further include third instruction data regarding the third target semiconductor IP. The scheduler 521 may schedule the execution of a test on the third target semiconductor IP such that a test operation on the third target semiconductor IP is performed after a test operation on the fourth target semiconductor IP is completed.

Referring to FIGS. 12 and 13, the test operations on the fourth and sixth semiconductor IPs may be performed in parallel. The polling operations on the fourth and sixth semiconductor IPs may be simultaneously performed, as described above with reference to FIG. 11. After the test operation on the sixth semiconductor IP is completed, a test operation on the first semiconductor IP may be performed. While the test operation on the first semiconductor IP is performed prior to the test operation on the fourth semiconductor IP in FIG. 11 (e.g., is initiated prior to the test operation on the fourth semiconductor IP), the test operation on the fourth semiconductor IP is performed prior to the test operation on the first semiconductor IP (e.g., is initiated prior to the test operation on the first semiconductor IP) in FIG. 13. A sum time-out time TIME-OUT may be 1,050 that is the sum of 300, 350, and 400. The timer 523 may count the number of cycles from the start of the test operation on the sixth semiconductor IP. When the counted number of cycles reaches 1,050, a time-out on all of the test operations has occurred. In the embodiment of FIG. 13, if all of the test operations do not time-out, then an overall time taken for test operations on the three semiconductor IPs can be shortened.

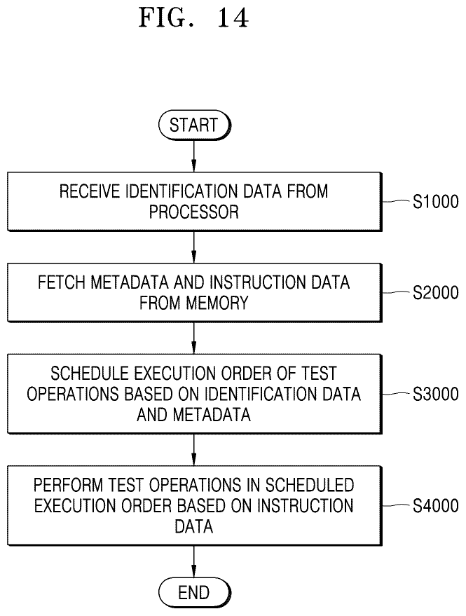

FIG. 14 is a flowchart of an operating method of a test device, according to an embodiment.

Referring to FIG. 14, identification data may be received from a processor in operation S1000. For example, the test device 500 may receive identification data, which specifies each of target semiconductor IPs to be tested, from the processor 50.

Metadata and a plurality of pieces of instruction data may be fetched from a memory in operation S2000. For example, the test device 500 may fetch metadata and at least one piece of instruction data from the memory 110.

An execution order of the target semiconductor IPs may be scheduled based on the identification data and the metadata in operation S3000. For example, in the parallel mode, the test device 500 may schedule the execution order of independent target semiconductor IPs first, based on the dependent relationship DEPENDENCY and the time-out time TIME-OUT in the metadata. The test execution on the independent target semiconductor IPs may be scheduled in descending order of time-out values. Thereafter, the test device 500 may schedule the execution order of dependent target semiconductor IPs.

In an embodiment, operation S2000 may include fetching the metadata, fetching first instruction data, and fetching second instruction data regarding a second target semiconductor IP. The metadata may include first relationship values representing independency between a first target semiconductor IP and the second target semiconductor IP, a first time-out value representing the time-out time of the first target semiconductor IP, and a second time-out value representing the time-out time of the second target semiconductor IP. The first instruction data may include a first value indicating a polling operation and a first expected value that is expected from a first polling operation performed on the first target semiconductor IP. The second instruction data may include the first value and a second expected value that is expected from a second polling operation performed on the second target semiconductor IP. Alternatively, the second instruction data may include a second value, which indicates an operation (e.g., a read or write operation) different from the polling operation, and a value (e.g., an expected value or a write value) according to the operation, which is different from the polling operation and performed on the second target semiconductor IP. In operation S3000, the test device 500 may schedule the first target semiconductor IP and the second target semiconductor IP for test execution, based on a first time-out value and a second time-out value, such that a time during which a test operation is performed on the first target semiconductor IP partially overlaps a time during which a test operation is performed on the second target semiconductor IP so that the test operations on the first and second target semiconductor IPs are performed in parallel.

In an embodiment, the test device 500 may sequentially schedule a test execution on target semiconductor IPs such that, after a test operation on one target semiconductor IP is completed, a test operation on another target semiconductor IP is performed, in operation S3000.

A test operation may be performed in the scheduled execution order based on the pieces of instruction data in operation S4000. For example, the test device 500 may perform a test operation on a target semiconductor IP.

In an embodiment, the operating method of a test device may further include receiving an address value of a target semiconductor IP, on which a test operation is currently being performed, from the processor and stopping the test operation on the target semiconductor IP.

In an embodiment, the operating method of a test device may further include, after the test operation on the target semiconductor IPs is completed, repeatedly performing the test operation on the target semiconductor IPs in the scheduled execution order at preset intervals.

While the inventive concept has been particularly shown and described with reference to embodiments thereof, it will be understood that various changes in form and details may be made therein without departing from the spirit and scope of the following claims.

What is claimed is:

1. An electronic device comprising:
a register configured to store mode data and identification data, the mode data specifying timing schemes for test operations on semiconductor intellectual properties (IPs), and the identification data specifying each of target semiconductor IPs to undergo a test operation among a plurality of semiconductor IPs;
a fetcher configured to fetch metadata and a plurality of pieces of instruction data from a memory, the metadata including a dependency relationship indication between and among the plurality of semiconductor IPs and a time-out time of the respective test operation on each of the plurality of semiconductor IPs, and the plurality of pieces of instruction data each including a type of operation and an address of each of a respective target semiconductor IP and a test sample according to the type of operation;
a driver configured to communicate with the target semiconductor IPs according to a scheduled execution order; and
a manager configured to schedule an execution order of test operations on the target semiconductor IPs, based on the mode data and the metadata, to provide the plurality of pieces of instruction data to the driver according to the scheduled execution order, and to output a test result based on a test response value of each of the target semiconductor IPs from the driver.

2. The electronic device of claim 1, wherein:
the mode data further includes a first mode value indicating a sequential mode, and
the manager is further configured to sequentially schedule a test execution on the target semiconductor IPs, wherein, after the test operation on each one of the target semiconductor IPs is completed, the test operation on a next target semiconductor IP is performed according to the execution order.

3. The electronic device of claim 2, wherein:
the mode data further includes a second mode value indicating a parallel mode,
the metadata further includes:
first relationship values representing independency of a first target semiconductor IP and a second target semiconductor IP, a first time-out value representing a time-out time of the first target semiconductor IP, and a second time-out value representing a time-out time of the second target semiconductor IP,
the plurality of pieces of instruction data include:
first instruction data including a first value indicating a polling operation and a first expected value expected from a first polling operation performed on the first target semiconductor IP; and
second instruction data including the first value and a second expected value expected from a second polling operation performed on the second target semiconductor IP, and
the manager is further configured to:
schedule the first target semiconductor IP and the second target semiconductor IP for a test execution, based on the first time-out value and the second time-out value, wherein a time during which a test operation is performed on the first target semiconductor IP partially overlaps a time during which a test operation is performed on the second target semiconductor IP so that the test operations on the first and second target semiconductor IPs are performed in parallel.

4. The electronic device of claim 3, wherein:
the first polling operation and the second polling operation are alternately performed, and when one of the first polling operation and the second polling operation fails, the other polling operation continues to be performed, and
the manager is further configured to
schedule a test on a target semiconductor IP corresponding to a larger time-out value between the first time-out value and the second time-out value to initiate execution before initiation of a test on a target semiconductor IP corresponding to a smaller time-out value between the first time-out value and the second time-out value.

5. The electronic device of claim 3, wherein:
the manager is further configured to
sum the first time-out value and the second time-out value, set a sum time-out value,
determine, based on the sum time-out value, whether the test operations on the first target semiconductor IP and the second target semiconductor IP are timed out, and
process a test result for a timed-out target semiconductor IP as a fail.

6. The electronic device of claim 3, wherein:
the metadata further includes a second relationship value indicating a relationship in which a third target semiconductor IP is dependent on the first target semiconductor IP,
the pieces of instruction data further include third instruction data regarding the third target semiconductor IP, and
the manager is further configured to:
schedule an execution order of the third target semiconductor IP, wherein a test operation on the third target semiconductor IP is performed after the test operation on the first target semiconductor IP is completed.

7. The electronic device of claim 2, wherein:
the mode data further includes a second mode value indicating a parallel mode,
the metadata further includes first relationship values representing independency between a first target semiconductor IP and a second target semiconductor IP,
the plurality of pieces of instruction data include:
first instruction data including a first value indicating a polling operation and a first expected value expected from a first polling operation performed on the first target semiconductor IP; and
second instruction data including a second value indicating a different operation than the polling operation and a value according to the different operation performed on the second target semiconductor IP, and
the manager is further configured to:
schedule a test on the first target semiconductor IP to initiate execution before a test on the second target semiconductor IP, wherein a time during which a test operation is performed on the first target semiconductor IP at least partially overlaps a time during which a test operation is performed on the second target semiconductor IP and the different operation of the second target semiconductor IP is performed when the first polling operation fails.

8. The electronic device of claim 1, further comprising:
a blocker configured to receive, from a processor, an address value of a target semiconductor IP currently undergoing a test operation among the target semiconductor IPs and stop the test operation on the target semiconductor IP.

9. The electronic device of claim 1, wherein the manager is further configured to
schedule the execution order of test operations on the target semiconductor IPs, wherein, when the test operations on the target semiconductor IPs are completed, the test operations on the target semiconductor IPs are subsequently performed at preset intervals.

10. An electronic device comprising:
a plurality of semiconductor intellectual properties (IPs);
a memory storing metadata and a plurality of pieces of instruction data, the metadata including a dependency relationship indication between and among the plurality of semiconductor IPs and a time-out time of a test operation on each of the plurality of semiconductor IPs, and the plurality of pieces of instruction data each including a type of operation and an address of a respective one of the plurality of semiconductor IPs and a test sample according to the type of operation; and
a tester configured to schedule an execution order of test operations on target semiconductor IPs, based on the metadata and identification data received from a processor and specifying each of the target semiconductor IPs, to perform the test operations on the target semiconductor IPs in the scheduled execution order based on instruction data regarding the target semiconductor IPs, and to provide the processor with a test result based on a test response value of each of the target semiconductor IPs.

11. The electronic device of claim 10, wherein the tester is further configured to sequentially schedule a test execution on the target semiconductor IPs, wherein, after the test operation on one of the target semiconductor IPs is completed, the test operation on another target semiconductor IP is performed according to the execution order.

12. The electronic device of claim 10, wherein:
the metadata further includes:
first relationship values representing independency between a first target semiconductor IP and a second target semiconductor IP, a first time-out value representing a time-out time of the first target semiconductor IP, and a second time-out value representing a time-out time of the second target semiconductor IP,
the plurality of pieces of instruction data include:
first instruction data including a first value indicating a polling operation and a first expected value expected from a first polling operation performed on the first target semiconductor IP; and
second instruction data including the first value and a second expected value expected from a second polling operation performed on the second target semiconductor IP, and
the tester is further configured to:
schedule the first target semiconductor IP and the second target semiconductor IP for a test execution, based on the first time-out value and the second time-out value, wherein a time during which a test operation is performed on the first target semiconductor IP partially overlaps a time during which a test operation is performed on the second target semiconductor IP and the test operations on the first and second target semiconductor IPs are performed in parallel.

13. The electronic device of claim 10, wherein:
the metadata further includes:
first relationship values representing independency between a first target semiconductor IP and a second target semiconductor IP,
the plurality of pieces of instruction data include:
first instruction data including a first value indicating a polling operation and a first expected value expected from a first polling operation performed on the first target semiconductor IP; and
second instruction data including a second value indicating a different operation than the polling operation and a value according to the different operation performed on the second target semiconductor IP, and
the tester is further configured to:
schedule a test on the first target semiconductor IP to initiate execution before initiation of a test on the second target semiconductor IP, wherein a time during which a test operation is performed on the first target semiconductor IP at least partially overlaps a time during which a test operation is performed on the second target semiconductor IP and the different operation of the second target semiconductor IP is performed when the first polling operation fails.

14. The electronic device of claim 10, wherein:
the tester is further configured to:
receive, from the processor, an address value of a target semiconductor IP currently undergoing a test operation among the target semiconductor IPs, and
stop the test operation on the target semiconductor IP.

15. The electronic device of claim 10, wherein:
the tester is further configured to:
schedule the execution order of test operations on the target semiconductor IPs, wherein, when the test operations on the target semiconductor IPs are completed, subsequent test operations on the target semiconductor IPs are performed at preset intervals.

16. An operating method of a test device, the operating method comprising:
receiving identification data from a processor, the identification data specifying each of target semiconductor intellectual properties (IPs) to undergo a test operation among a plurality of semiconductor IPs;
fetching metadata and a plurality of pieces of instruction data from a memory, the metadata including a dependency relationship indication between the plurality of semiconductor IPs and a time-out time of the test operation on each of the plurality of semiconductor IPs, and the plurality of pieces of instruction data each including a type of operation and an address of each of the target semiconductor IPs and a test sample according to the type of operation;
scheduling an execution order of test operations on the target semiconductor IPs based on the identification data and the metadata; and
performing the test operations on the target semiconductor IPs in the scheduled execution order based on the plurality of pieces of instruction data.

17. The operating method of claim 16, wherein:
the scheduling of the execution order includes:
sequentially scheduling test execution on the target semiconductor IPs, wherein after the test operation on one of the target semiconductor IPs is completed, the test operation on another target semiconductor IP is performed.

18. The operating method of claim 16, wherein:
the fetching includes:
fetching the metadata including first relationship values representing independency between a first target semiconductor IP and a second target semiconductor IP, a first time-out value representing a time-out time of the first target semiconductor IP, and a second time-out value representing a time-out time of the second target semiconductor IP;
fetching first instruction data including a first value indicating a polling operation and a first expected value expected from a first polling operation performed on the first target semiconductor IP; and
fetching second instruction data regarding the second target semiconductor IP, and
the scheduling includes
scheduling the first target semiconductor IP and the second target semiconductor IP for a test execution, based on the first time-out value and the second time-out value, wherein a time during which a test operation is performed on the first target semiconductor IP partially overlaps a time during which a test operation is performed on the second target semiconductor IP and the test operations on the first and second target semiconductor IPs are performed in parallel.

19. The operating method of claim 16, further comprising:
receiving, from the processor, an address value of a target semiconductor IP currently undergoing a test operation among the target semiconductor IPs; and
stopping the test operation on the target semiconductor IP.

20. The operating method of claim 16, further comprising,
when the test operations on the target semiconductor IPs are completed, subsequently performing the test operations on the target semiconductor IPs in a scheduled execution order at preset intervals.
